(19) United States
(12) Patent Application Publication
(10) Pub. No.: US 2026/0358437 A1
(43) Pub. Date: Nov. 12, 2026

(54) METHOD FOR MONITORING A JOINING PROCESS OF A FLEX CABLE AND FLEX CABLE

(71) Applicant: Robert Bosch GmbH, Stuttgart (DE)

(72) Inventors: Michael Mayer, Hohenstein (DE); Wolfram Kienle, Magstadt (DE); Frank Brielmann, Moessingen (DE)

(21) Appl. No.: 19/125,083

(22) PCT Filed: Oct. 27, 2023
(86) PCT No.: PCT/EP2023/080113

§ 371 Date: Apr. 28, 2025

(30) Foreign Application Priority Data
Nov. 8, 2022 (DE) 10 2022 211 784.0

(51) Int. Cl. G01R 31/69

(52) U.S. Cl. CPC G01R 31/69

(57) ABSTRACT

The present invention relates to a method for monitoring a joining process of a flex cable (10) and to such flex cable (10). The method comprises: a first step for using a first mounting portion (12) and a second mounting portion (14) of the flex cable (10) in order to pull the flex cable (10) in a joining direction (20) of a plug (30) to which the flex cable (10) is to be connected, wherein the plug (30) is attached to a first side (42) of a circuit board (40), wherein the mounting portions (12, 14) are elongate projections on respective sides of the flex cable (10), which projections extend in a longitudinal direction of the flex cable (10) beyond a contacting region (16) and which are guided through corresponding openings (46) in the circuit board (40) in order to pull the mounting portions (12, 14) from a second side (44) of the circuit board (40) in the direction of the joining direction (20) of the plug (30); and a second step for using the parts of the first mounting portion (12) and/or the second mounting portion (14) that are accessible on the second side (44) of the circuit board (40) after joining in order to check a correct joining state of the flex cable (10) and the plug (30) on the basis of an electrical and/or optical and/or mechanical property of the first mounting portion (12) and/or the second mounting portion (14).

### BACKGROUND

The present invention relates to a method for monitoring a joining process of a flex cable and to such a flex cable.

In the power electronics, power semiconductors are controlled by means of switch signals, which are transmitted via different line paths or different technical solutions. For example, in order to control power semiconductors using DBC or AMB-based techniques, bonding, pressing-in of punched parts and the use of connecting elements, which are configured as cables and/or flex cables are conceivable.

In order to implement a connection solution by means of a flex cable, a plug is first mounted on a circuit board, with which an electrical contacting region of the flex cable is to be contacted during a joining process of the flex cable and the plug. In this context, arrangements are known in which the plug is located on an externally accessible and visible top side of the circuit board and the flex cable is to be guided from a bottom side of the circuit board to the plug. For this purpose, corresponding openings are provided in the circuit board through which the flex cable is guided from the bottom side of the circuit board to the top side of the circuit board, in order to be subsequently connected to the plug in the horizontal or vertical direction, depending on the arrangement of the plug.

Since the joining process and the result of the joining process can be visually controlled in this way, a correctly executed joint connection can be easily ensured in such a case.

### SUMMARY

According to a first aspect of the present invention, a method for monitoring a joining process of a flex cable, and in particular a method for monitoring a joining process not visible from the outside or only to a limited extent, is proposed.

Such a flex cable, which is also referred to as a film cable or flat cable, is made of a flexible material and generally comprises a plurality of individual electrical conductors or wires, which are generally guided from one end of the flex cable to another end of the flex cable in order to establish an electrical connection between components via said flex cable. The flex cable can be configured as a single-layer or multi-layer flex cable, and electrical components and/or circuitry can also be pre-mounted on and/or integrated into the flex cable. Particularly advantageously, the flex cable comprises a latching device (e.g., one or more latching tabs) at one and preferably at both ends of the flex cable to be contacted to enable a form-fit connection with plugs to be connected. Alternatively or additionally, it is possible for the flex cable to be connected to the plugs by means of a force-fit connection, for example by inserting clamping devices provided on the plugs for connection. A material-locking connection is also generally conceivable in this context.

The method comprises a first step for using a first mounting portion and a second mounting portion of the flex cable in order to pull the flex cable in a joining direction of a plug to which the flex cable is to be connected, wherein the plug is attached to a first side of a circuit board and the joining direction of the plug is transverse, in particular perpendicular, to the plane of the circuit board. The first mounting portion and the second mounting portion are each elongate protrusions on respective sides of a contacting region of the flex cable to be connected to the plug and which extend in a longitudinal direction of the flex cable beyond the contacting region of the flex cable. The contacting region is an area at the end of the flex cable at which the wires of the flex cable are accessible for electrical contacting.

The first mounting portion and the second mounting portion for joining the flex cable are guided through corresponding openings in the circuit board starting from the first side in order to pull the mounting portions from a second side of the circuit board opposite the first side in the direction of the joining direction of the plug. For example, the first side of the circuit board is a bottom side of the circuit board, which, due to a mounting situation and/or a pre-assembled state of the circuit board, is not visible and/or accessible to a limited extent at least in the joining area of the plug and the flex cable, for example from the outside. Accordingly, the second side of the circuit board is, for example, a top side of the circuit board, which is visible and/or accessible from the outside for control of the joining process and/or the joining state. In other words, both a contacting region of the plug and a contacting region of the flex cable are located on the first side of the circuit board, which is potentially not accessible or only accessible to a limited extent for control, during and after the joining process, wherein the method is of course also advantageously applicable in such a case in which the first side is also accessible for an external control of the joining process and/or the joint connection.

It should be noted that additional mounting aids, such as a centering device, etc., may be provided for the joining process according to the invention in order to enable a simpler and/or more reliable assembly of the flex cable, in particular in the case of a “blind” or hidden joining process.

In a second step of the method according to the invention, the parts of the first mounting portion and/or the second mounting portion that are accessible on the second side of the circuit board after joining are used to check a correct joining state of the flex cable and the plug on the basis of an electrical and/or optical and/or mechanical property of the first mounting portion and/or the second mounting portion.

The method according to the invention offers the particular advantage that a joint connection of the flex cable with a corresponding plug can also be monitored particularly reliably if a joining area of the flex cable and the plug is not accessible or only accessible to a limited extent or visible due to an installation situation. This makes it possible, among other things, to use of a joint connection in which both the plug and the flex cable are joined to a bottom side of a circuit board, which means that, compared to the prior art, only small openings need to be provided in the circuit board for the mounting portions to pass through, since the flex cable does not have to be guided across its full width from one side of the circuit board to the other side of the circuit board. This can in particular save space on the second side of the circuit board, which can be used, for example, for the arrangement of components and/or for the reduction of a total size of the circuit board.

In an advantageous embodiment of the present invention, the method further comprises a step of using the result of the check of the joining state in order to correct and/or label an incorrect joining state and/or to output information about the joining state. The correction can be advantageously performed by means of an assembly tool, which is used for the joining process to be performed in the first method step. A faulty joining state is identified by means of a marking, for example, which is attached to the second side of the circuit board. For example, information about the joining state is output as an optical and/or audible and/or haptic indication in a mobile terminal device and/or in a monitoring unit of a production line.

In a particularly advantageous embodiment of the present invention, the flex cable comprises at least one test contact within the contacting region of the flex cable connected to an electrical conductor of the flex cable that is guided up to the first mounting portion and/or the second mounting portion, so that the electrical conductor can be electrically contacted by the second side of the circuit board at least in the joining state of the flex cable and the plug. To check the correct joining state of the flex cable, an electrical conductivity is determined between the electrical conductor in the first mounting portion and/or in the second mounting portion and a contact of the plug corresponding to the test contact, which can be contacted by the second side of the circuit board. A position of the test contact within the contacts in the contacting region is generally not restricted. For example, it is possible to arrange the test contact in the center or off the center of the contacting region. Furthermore, it is possible that the contact of the plug used for checking the conductivity may be configured as a pad on the printed circuit board to facilitate electrical contacting. The measurement of the electrical conductivity is carried out, for example, by means of the mounting tool, which is used for joining the flex cable and the plug. Alternatively or additionally, a dedicated test tool can be used for this purpose. For example, the electrical conductivity is checked by applying a voltage between the electrical conductor in the mounting portion and the contact of the plug corresponding to the test contact and/or the pad electrically connected to the contact of the plug. A conductivity can then be determined on the basis of a measured current and/or resistance within the measuring arrangement. In the exemplary case that a current flowing exceeds a predefined current threshold value and/or a resistance value drops below a predefined resistance value, a correct joint connection between the plug and the flex cable must be assumed accordingly.

The at least one test contact is particularly advantageously configured smaller than further contacts of the contacting region and/or arranged offset to (“lagging”) the further contacts of the contacting region, such that during the joining process, the further contacts are first contacted with respective contacts of the plug and the at least one contact is only then contacted with a corresponding contact of the plug, when the joining process is completed without errors. This may further increase the reliability in checking the correctness of the joint connection, as it further reduces the likelihood that a faulty joint connection will be present at an existing current flow through the test contact.

Preferably, the test contact is a first test contact that can be contacted via the first mounting portion. Moreover, the flex cable advantageously comprises a second test contact, which can be contacted via the second mounting portion. Alternatively or additionally, the first test contact and/or the second test contact are each the outermost contacts within the preferably parallel arranged contacts of the contacting region. Further alternatively or additionally, the correct joining state of the flex cable is checked by means of separate conductivity measurements between the test contacts and their respective corresponding mounting portions and/or by means of a common conductivity measurement, in which the electrical conductors of the two mounting portions or the contacts of the plug corresponding to the test contacts are directly electrically connected. The contacts of the plug corresponding to the test contacts can be permanently connected, for example by means of one or more conductor paths of the circuit board. Alternatively or additionally, it is possible that an electrical connection is made between the contacts of the plug, which correspond to the test contacts, by the mounting tool used and/or by a separate test tool. The common conductivity measurement provides the advantage of simplified contacting by the mounting tool and/or the dedicated test tool, as only the two electrical conductors of the mounting portions or only the two corresponding contacts of the plug for the conductivity measurement need to be contacted to establish a common circuit across both test contacts. In addition, only one measuring circuit is required. The separate conductivity measurements, on the other hand, offer the advantage that the correct contacting of the first test contact and the second test contact can be independently checked so that different contacting errors can be distinguished between the flex cable and the plug.

In a further advantageous embodiment of the present invention, the at least one test contact is a contact used in a productive insert of the flex cable for signal transmission and/or an electrical power supply. This provides the advantage that no additional contacts and leads within the flex cable must be provided for checking the correctness of the joint connection, which no longer have a purpose in a productive insert after successful testing, but for which a space and material requirement must be provided. In this way, the flex cable can be formed more cost-effectively and/or in a more space-saving manner. Alternatively or additionally, by using at least two test contacts having a predefined distance to each other, a type of error state, in particular a direction of a tilting of the flex cable with respect to the plug, is determined. The information about the specific error case can be used particularly advantageously for a targeted correction of a faulty joint connection.

In a further advantageous embodiment of the present invention, the correct joining state of the flex cable and the plug is checked by applying a force to the first mounting portion and/or the second mounting portion in the joining state by means of a test tool, which acts in an direction opposite to the joining direction, and by measuring whether the force reaches a predefined target value and/or whether the predefined target value is maintained for a predefined time period and/or whether a position of the flex cable and/or the test tool remains substantially unchanged within the predefined time period. In other words, in this case a mechanical test of the correctness of the joint connection is carried out by applying a force to one or both of the mounting portions, the effect of which allows a conclusion to be drawn about the correctness of the joint connection and/or a specific error state. The determined information can be used for a targeted correction of the joint connection by the mounting tool and/or the test tool. In the exemplary case that the first mounting portion yields by applying the force in the opposite direction to the joining direction while the second mounting portion remains unchanged, it may be assumed, for example, that the flexible cable has not snapped into the plug on the side of the first mounting area. By pulling the first mounting portion again in the joining direction, this error can be corrected if necessary. Advantageously, the mechanical test described above takes place again after the correction has been completed.

In a further advantageous embodiment of the present invention, the correct joining state is checked by using an optical sensor (e.g., an RGB and/or a monochrome camera) to detect a position and/or a variable and/or an orientation of the first mounting portion and/or the second mounting portion relative to the circuit board is detected (e.g., via a marking on the circuit board and/or via a reference object arranged on the circuit board and/or via a characteristic assembly and/or via a conductor track pattern of the circuit board, etc.) and by determining whether the variables detected by the optical sensor (i.e., the position and/or the size and/or the orientation) correspond to predefined corresponding target values.

According to a second aspect of the present invention, a flex cable is proposed which comprises at least one contacting region with a plurality of contacts arranged in parallel, wherein at least one of the contacts represents a test contact and which has a first mounting portion and a second mounting portion, wherein the flex cable is configured to be connected to a corresponding plug (reversible or irreversible), such that the contacts of the contacting region make electrical connections with respective corresponding contacts of the plug. The first mounting portion and the second mounting portion are each elongate protrusions on respective sides of the contacting region of the flex cable, which extend in a longitudinal direction of the flex cable beyond the contacting region of the flex cable. Furthermore, the first mounting portion and the second mounting portion are configured to be pulled towards the plug to be connected to join the flex cable and the plug. In addition, the at least one test contact is connected to an electrical conductor of the flex cable which is guided up to the first mounting portion and/or the second mounting portion, such that the electrical conductor is configured to be electrically contacted via the first mounting portion and/or the second mounting portion.

The at least one test contact of the flex cable is particularly advantageous smaller than the further contacts of the contacting region and/or arranged offset to (“lagging”) the further contacts of the contacting region, such that the test contact is configured to only be contacted with a corresponding plug during a joining process of the flex cable if the further contacts are already in contact with respective contacts of the plug.

### BRIEF DESCRIPTION OF THE DRAWINGS

In the following, exemplary embodiments of the invention are described in detail with reference to the accompanying drawings. Shown are:

FIG. 1 a schematic view of a flex cable according to the invention in a first embodiment and a corresponding plug prior to a joining process;

FIG. 2a a schematic view of the flex cable according to the invention in the first embodiment and the corresponding plug during a first test of the joining state according to the invention;

FIG. 2b a schematic view of the flex cable according to the invention in the first embodiment and the corresponding plug during a second test of the joining state according to the invention;

FIG. 2c a schematic view of the flex cable according to the invention in the first embodiment and the corresponding plug during a third test of the joining state according to the invention;

FIG. 3 a schematic view of the flex cable according to the invention in a second embodiment and a corresponding plug during a further test of the joining state according to the invention; and FIG. 4 a schematic view of a flex cable according to the invention in the second embodiment during a further test of a joining state according to the invention.

### DETAILED DESCRIPTION

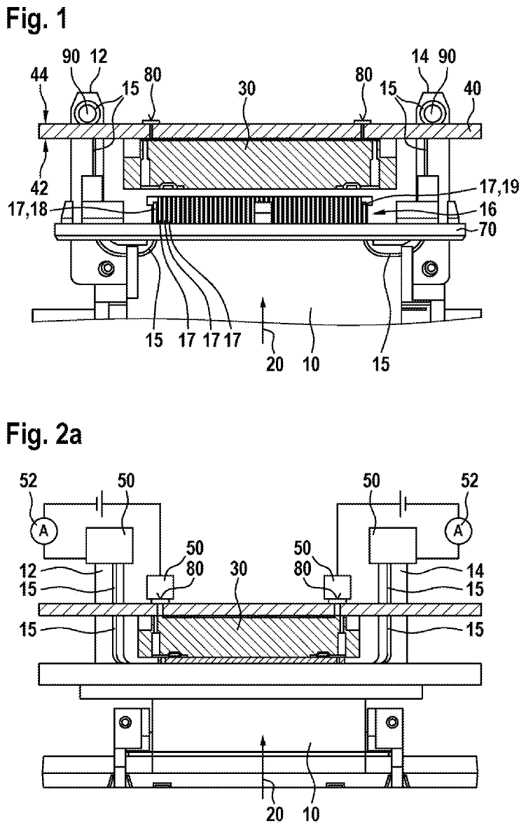

FIG. 1 shows a schematic view of a flex cable 10 according to the invention in a first embodiment and a corresponding plug 30 prior to a joining process of the two components 10, 30, wherein the joining process for establishing electrical contacting is carried out between contacts 17 of the flex cable 10 and corresponding contacts of the plug 30.

The flex cable 10, which comprises a plurality of wires for establishing an electrical connection, which can be contacted via the contacts 17 of the flex cable 10, is in a preparation state here for performing the joining process between the flex cable 10 and the plug 30. The plug 30 is mounted on a first side 42 of a circuit board 40. In this preparation state, the flex cable 10 is inserted into a centering unit 70, which ensures guidance of the flex cable 10 during the subsequent joining process.

The flex cable 10 has a first mounting portion 12 and a second mounting portion 14, which are used in a subsequent joining process to pull the flex cable 10 in a joining direction 20 of the plug 30, with which the flex cable 10 is to be contacted. The joining direction 20 is perpendicular to the plane of the circuit board 40 here.

The first mounting portion 12 and the second mounting portion 14 are each elongate protrusions on respective sides of a contacting region 16 of the flex cable 10 to be connected to the plug 30 and which extend in a longitudinal direction of the flex cable 10 beyond the contacting region 16 of the flex cable 10. The mounting portions 12, 14 here also each have punching holes 90 in their end portions, into which a mounting tool (not shown) can engage to facilitate the joining process. It should be noted, however, that the punching holes 90 are not absolutely necessary for the performance of the joining process and can thus be omitted.

The first mounting portion 12 and the second mounting portion 14 are guided in the preparation state through corresponding openings 46 (which are visible in FIG. 4) in the circuit board 40 in order to pull the mounting portions 12, 14 in the subsequent joining process from a second side 44 of the circuit board 40, which is opposite the first side 42, in the direction of the joining direction 20 of the plug 30.

The flex cable 10 also has a first test contact 18 within the contacting region 16 of the flex cable 10, which is connected to an electrical conductor 15 of the flex cable 10 that is guided up to the first mounting portion 12, such that the first test contact 18 can be electrically contacted via the first mounting portion 12.

The flex cable 10 further comprises a second test contact 19 within the contacting region 16 of the flex cable 10, which is connected to an electrical conductor 15 of the flex cable 10 that is guided up to the second mounting portion 14, such that the second test contact 19 can be electrically contacted via the second mounting portion 14.

The first test contact 18 and the second test contact 19 are each the outermost contacts 17 of the contacting region 16 of the flex cable 10, without being limited to such an arrangement. In addition, both test contacts 18, 19 are arranged offset to (“lagging”) the further parallel arranged contacts 17 of the contacting region 16, such that when the joining process is carried out, the further contacts 17 first come into contact with the contacts of the plug 30 before the test contacts 18, 19 come into contact with their corresponding contacts of the plug 30. The test contacts 18, 19 are configured to assume a correct joining state of the flex cable 10 and the plug 30 when they establish an electrical connection with their corresponding contacts of the plug 30.

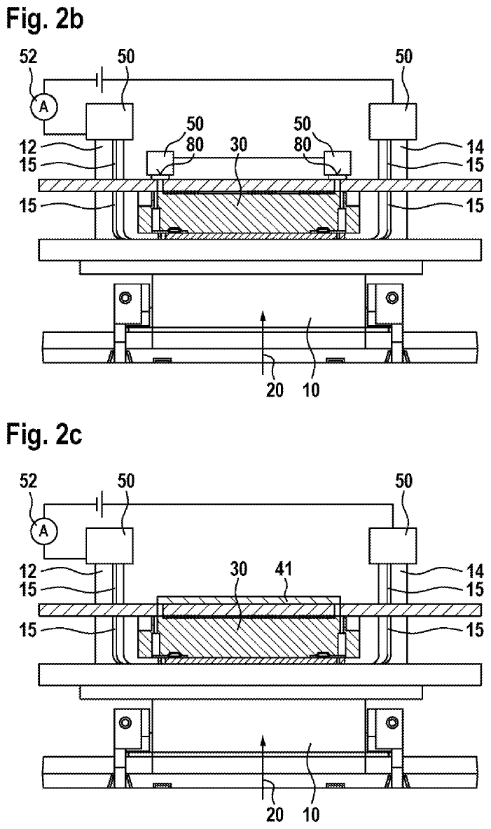

The contacts of the plug 30 corresponding to the test contacts 18, 19 are electrically connected to each pad 80 provided on the second side 44 of the circuit board 40 for electrical contacting by a test tool 50 shown in FIG. 2.

FIG. 2a shows a schematic view of the flex cable 10 according to the invention in the first embodiment and the corresponding plug 30 during a first test of the joining state according to the invention between the flex cable 10 and the plug 30.

Since FIG. 2a shows the flex cable 10 and the plug 30 according to FIG. 1 in the joining state now, only the differences between FIGS. 1 and 2a are substantially explained below to avoid repetitions.

In FIG. 2a, the joining process is completed by pulling the flex cable 10 into the joining direction 20 so that checking the correctness of the joining state can begin. This is done here on the basis of a measurement of an electrical current by means of respective current sensors 52 to ensure an electrical conductivity between the test contacts 18, 19 and their respective corresponding contacts of the plug 30.

In this case, a test tool 50 is electrically connected to the pads 80 and the corresponding electrical conductors 15 in the mounting portions 12, 14, such that a current flow can be measured when the test contacts 18, 19 are correctly connected to the plug 30.

By separately checking the first test contact 18 and the second test contact 19, it is possible to precisely identify a potentially existing error state, as this makes it possible to determine which of the test contacts 18, 19 may be incorrectly contacted, such that a targeted correction of the error can advantageously be made on the basis of this information.

It should be noted that the two pads 80 on the second side of the circuit board 40 may be permanently or temporarily electrically connected, such that alternatively a total current measurement may be made between the electrical conductor 15 in the first mounting portion 12 and the electrical conductor 15 in the second mounting portion 14.

FIG. 2b shows a schematic view of the flex cable according to the invention in the first embodiment and the corresponding plug during a second test of the joining state according to the invention.

In order to avoid repetitions, only the differences between FIG. 2b and FIG. 2a are explained below and otherwise reference is made to the description of FIG. 2a.

In FIG. 2b, the correctness of the joining state is checked on the basis of a single voltage source and a single current sensor 52 by connecting the contacts of the respective test tools 50 according to the illustration in FIG. 2b, whereby in the event of a correct joining state, a circuit is closed via the test tools 52.

FIG. 2c shows a schematic view of the flex cable according to the invention in the first embodiment and the corresponding plug during a third test of the joining state according to the invention.

In order to avoid repetitions, only the differences between FIG. 2c and FIG. 2b are explained below and otherwise reference is made to the description of FIGS. 2a and 2b.

In FIG. 2c, the correctness of the joining state is checked by closing the circuit via a conductive path 41 arranged on the circuit board 40, which electrically connects contacts of the plug 30 corresponding to the test contacts 18, 19.

Accordingly, the test tools 50, which in FIGS. 2a and 2b contact the contact surfaces 80 (which are not required in FIG. 2c) are omitted because the circuit is closed via the conductor path 41, provided a correct joining state is present.

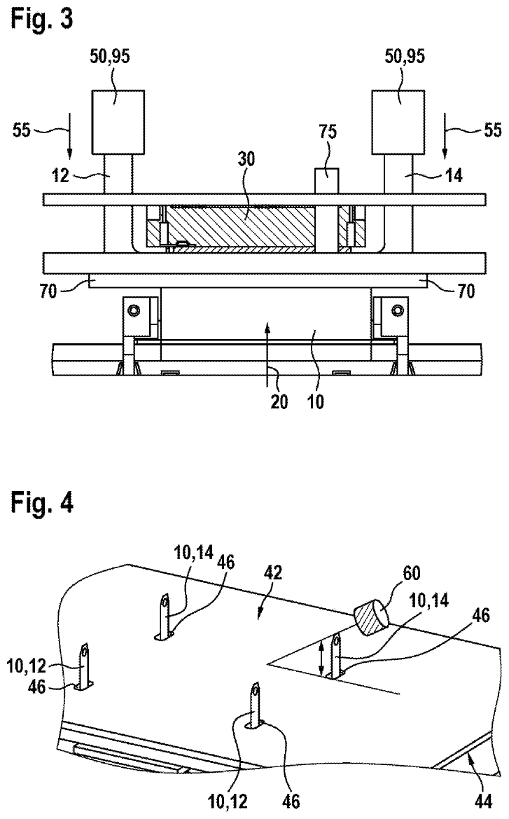

FIG. 3 shows a schematic view of a flex cable 10 according to the invention in a second embodiment and a corresponding plug 30 during a further test of a joining state according to the invention.

Given the numerous similarities between FIGS. 1, 2 and FIG. 3, only their differences between FIG. 3 and FIGS. 1 and 2 are described below in order to avoid repetition.

In FIG. 3, the flex cable does not have any electrical conductors 15 in the mounting portions 12, 14 and no test contacts 18, 19, as in this case a purely mechanical test of the correct joint state between the flex cable 10 and the connector 30 is carried out. This does not exclude that such a mechanical test is also performed with a flex cable 10 configured according to FIGS. 1 and 2.

Here, the first mounting portion 12 and the second mounting portion 14 are acted upon in the joining state by a test tool 50 by means of a predefined test force 55, which acts in an opposite direction to the joining direction 20, wherein the test tool 50 here is simultaneously a mounting tool 95 for the joining process. The test force 55 is advantageously dimensioned such that it is less than a force that is configured to release a latched connection between the flex cable 10 and the plug 30 in the joining state, but which is large enough to detect a faulty joining state.

Based on the test force 55, it is measured whether the test force 55 reaches a predefined target value and whether the predefined target value is maintained for a predefined period of time and whether a position of the flex cable and the test tool remains substantially unchanged within the predefined time period. If the aforementioned conditions are met, a correct joining state must be assumed.

In FIG. 3, a centering pin 75 is additionally shown, which serves to position the centering unit 70 with respect to the circuit board 40. Such a centering pin 75 may also be advantageously applied in the configuration shown in FIG. 1, in FIG. 2a, in FIG. 2b, and in FIG. 2c.

FIG. 4 shows a schematic view of a flex cable 10 according to the invention in the second embodiment during a further test of a joining state according to the invention.

Here, a check of the correct joining state between respective flex cables 10 and respective plugs (not visible in this case) is carried out by means of an optical sensor configured as camera 60, which is configured to sense a position and a variable and an orientation of the respective first mounting portions 12 and the second mounting portions 14 with respect to the circuit board 40 on the second side 44 of the circuit board 40. The reference to the circuit board 40 is ensured here by an evaluation of a characteristic conductor track pattern (not shown). Based on the conductor track pattern, a target distance and target angle of the camera 60 with respect to the circuit board 40 can therefore be set and/or deviations in this respect can be compensated for by calculation, such that the target values of the mounting portions 12, 14 can be reliably checked.

A correct joining state can be determined in this manner if the variables detected by the camera 60 match predefined corresponding target sizes for the correct joining state.

In addition, FIG. 4 shows the openings 46 provided in the circuit board 40, through which the mounting portions 12, 14 of the respective flex cables 10 can be guided from the first side 42 of the circuit board 40 to the second side 44 of the circuit board 40.

1. A method for monitoring a joining process of a flex cable (10) comprising:
a first step (100) for using a first mounting portion (12) and a second mounting portion (14) of the flex cable (10) in order to pull the flex cable (10) in a joining direction (20) of a plug (30) to which the flex cable (10) is to be connected, wherein
the plug (30) is attached to a first side (42) of a circuit board (40) and the joining direction (20) of the plug (30) is transverse, to a plane of the circuit board (40),
the first mounting portion (12) and the second mounting portion (14) are each elongate protrusions on respective sides of a contacting region (16) of the flex cable (10) to be connected to the plug (30) and which extend in a longitudinal direction of the flex cable (10) beyond the contacting region (16) of the flex cable (10),
the first mounting portion (12) and the second mounting portion (14) for joining the flex cable (10) are guided through corresponding openings (46) in the circuit board (40) in order to pull the mounting portions (12, 14) from a second side (44) of the circuit board (40) opposite the first side (42) in the joining direction (20) of the plug (30), and
a second step (200) for using parts of the first mounting portion (12) and/or the second mounting portion (14) that are accessible on the second side (44) of the circuit board (40) after joining in order to check a correct joining state of the flex cable (10) and the plug (30) on a basis of an electrical and/or optical and/or mechanical property of the first mounting portion (12) and/or the second mounting portion (14).

2. The method according to claim 1 further comprising a step of using the result of the joining state check to correct and/or label an incorrect joining state and/or to output joining state information.

3. The method according to claim 1, wherein
the flex cable (10) comprises at least one test contact (18) within the contacting region (16) of the flex cable (10) connected to an electrical conductor (15) of the flex cable (10) that is guided up to the first mounting portion (12) and/or the second mounting portion (14), such that the electrical conductor (15) can be electrically contacted by the second side (44) of the circuit board (40) at least in the joining state of the flex cable (10) and the plug (30), and
to check the correct joining state of the flex cable (10), an electrical conductivity is determined between the electrical conductor (15) in the first mounting portion (12) and/or in the second mounting portion (14) and a contact of the plug (30) corresponding to the at least one test contact (18), which can be contacted by the second side (44) of the circuit board (40).

4. The method according to claim 3, wherein the at least one test contact (18) is configured smaller than further contacts (17) of the contacting region (16) and/or arranged offset to the further contacts (17) of the contacting region (16), such that during the joining process, the further contacts (16) are first contacted with respective contacts of the plug (30) and the at least one test contact (18) is only then contacted with a corresponding contact of the plug (30) when the joining process is completed without errors.

5. The method according to claim 3, wherein
the at least one test contact is a first test contact (18) that can be contacted via the first mounting portion (12), and the flex cable (10) has a second test contact (19) that can be contacted via the second mounting portion (14), and/or
the first test contact (18) and/or the second test contact (19) are each the outermost contacts within parallel arranged contacts (17, 18, 19) of the contacting region (16), and/or
the correct joining state of the flex cable (10) is checked by separate conductivity measurements between the test contacts (18, 19) and their respective corresponding mounting portions (12, 14) and/or by a common conductivity measurement, in which the electrical conductors (15) of the two mounting portions (12, 14) or the contacts of the plug (30) corresponding to the test contacts (18, 19) are directly electrically connected.

6. The method according to claim 3, wherein
the at least one test contact (18) is a contact used in a productive insert of the flex cable (10) for signal transmission and/or an electrical power supply, and/or
using at least two test contacts (18, 19) having a predefined distance to each other, a type of error state is determined.

7. The method according to claim 1, wherein the correct joining state is checked by
the first mounting portion (12) and/or the second mounting portion (14) being acted upon in the joining state by a test tool (50) by a force acting in a direction opposite to the joining direction (20), and
it is measured whether the force reaches a predefined target value and/or whether the predefined target value is maintained for a predefined period of time and/or whether a position of the flex cable (10) and/or the test tool (50) remains substantially unchanged within the predefined time period.

8. The method according to claim 1, wherein the correct joining state is checked by
detecting a position and/or a variable and/or an orientation of the first mounting portion (12) and/or the second mounting portion (14) relative to the circuit board (40) by an optical sensor (60), and
it is determined whether variables detected by the optical sensor (60) match predefined corresponding target variables.

9. A flex cable (10) comprising:
a contacting region (16) with a plurality of contacts (17) arranged in parallel, wherein at least one of the contacts (17) represents a test contact (18), and
a first mounting portion (12) and a second mounting portion (14),
wherein
the flex cable (10) is configured to be connected to a corresponding plug (30) such that the contacts (17, 18) of the contacting region (16) make electrical connections with respective corresponding contacts of the plug (30),
the first mounting portion (12) and the second mounting portion (14)
are each elongate protrusions on respective sides of the contacting region (16) of the flex cable (10), which extend in a longitudinal direction of the flex cable (10) beyond the contacting region (16) of the flex cable (10), and
are configured to be pulled in a direction of the plug (30) to be connected in order to join the flex cable (10) and the plug (30), and
the at least one test contact (18) is connected to an electrical conductor (15) of the flex cable (10) which is guided up to the first mounting portion (12) and/or the second mounting portion (14), such that the electrical conductor (15) is configured to be electrically contacted via the first mounting portion (12) and/or the second mounting portion (14).

10. The flex cable (10) according to claim 9, wherein the at least one test contact (18) is configured smaller than the further contacts (17) of the contacting region (16) and/or arranged offset to the further contacts (17) of the contacting region (16), such that the at least one test contact (18) is configured to be contacted with a corresponding plug (30) during a joining process of the flex cable (10) only when the further contacts (17) are already in contact with respective contacts of the plug (30).

11. The method according to claim 6, wherein the type of error state is a direction of a tilting of the flex cable (10) with respect to the plug (30).
